(19) United States
(12) Patent Application Publication
(10) Pub. No.: US 2012/0002779 A1
(43) Pub. Date: Jan. 5, 2012

(54) STATE DETECTION CIRCUIT AND SEMICONDUCTOR MEMORY DEVICE

(75) Inventors: Shintaro SHIMADA, Tokyo (JP); Hiroyasu YOSHIDA, Tokyo (JP)

(73) Assignee: ELPIDA MEMORY, INC., Tokyo (JP)

(21) Appl. No.: 12/846,266

(22) Filed: Jul. 29, 2010

(30) Foreign Application Priority Data
Jun. 30, 2010 (JP) 2010-148588

(51) Int. Cl. H03K 21/00

(52) U.S. Cl. 377/39

(57) ABSTRACT

A state detection circuit comprises: a first counter circuit that counts a series of first command signals indicative of start of an operation control; a second counter circuit that counts a series of second command signals indicative of completion of the operation control; a count coincidence detection circuit that detects coincidence between a count in the first counter circuit and a count in the second counter circuit; and a state storing circuit that is set by the series of first command signals and reset when coincidence is detected by the count coincidence detection circuit. The first and second counter circuits each comprise a binary counter.

### TECHNICAL FIELD

### Reference to Related Application

This application is based upon and claims the benefit of the priority of Japanese Patent Application No. 2010-148588, filed on Jun. 30, 2010, the disclosure of which is incorporated herein in its entirety by reference thereto.

The present invention relates to a state detection circuit and semiconductor memory device. More specifically, the present invention relates to operation control technology in a semiconductor memory device.

### BACKGROUND

A synchronous semiconductor memory device represented by a synchronous DRAM (Synchronous Dynamic Random Access Memory) is widely used in a main memory of a personal computer etc. The synchronous semiconductor memory device is a memory that inputs and outputs data in synchronization with a clock signal supplied by a controller. The clock frequency has become higher and higher every year in order to meet the requirement of high speed in recent years.

Most synchronous DRAMs can receive a new read command or write command while executing a read operation or write operation. In this case, after a series of operations corresponding to a previously received read command or write command has been completed, a series of operations corresponding to a newly received read command and write command is started successively. Therefore, these synchronous DRAMs require a detection circuit that detects when all read operations or write operations have been completed in order to receive an early power down.

Patent Document 1 describes a semiconductor device comprising a data transfer completion detection circuit that is used in a semiconductor device capable of receiving a new data transfer command such as a read command or write command while performing a data transfer operation and detects completion of data transfer. The data transfer completion detection circuit is used in a semiconductor device that can transfer data in response to a data transfer command and receive a new data transfer command while performing a series of data transfer operations and comprises a first means that stores a reception history of data transfer commands and a second means that generates based on the reception history stored in the first means a completion detection signal indicating completion of a data transfer operation.

More specifically, as shown in FIG. 7, the data transfer completion detection circuit comprises: a first counter 21 that performs shift operations in response to a generation of a read start signal RD; a second counter 22 that performs shift operations in response to a generation of a burst termination signal BE; and an SR latch circuit 25 that generates a read enable signal RE in response to a generation of the burst termination signal BE if the count in the first counter 21 is equal to the count in the second counter 22. The first counter 21 comprises latch circuits 21₁to 21₈ connected in series to perform shift operations. The second counter 22 comprises latch circuits 22₁to 22₈ connected in series. The NAND circuits 23₁to 23₈ detect, respectively, coincidence between a logical value outputted from the latch circuits 21₁ to 21₈ and a logical value outputted from the latch circuits 22₁ to 22₈ and reset the SR latch circuit 25 through the NAND circuit 24 if all values coincide. It is to be noted that the latch circuits 21₁ to 21₈, and 22₁ to 22₈ are initialized by an initial value setting circuit 26.

Since the data transfer completion detection circuit detects completion of a data transfer operation such as a read operation based on the reception history of the read start signal RD, the circuit can detect a time point at which all read operations have been completed even when the circuit receives a new read command while executing a read operation.

### [Patent Document 1]

JP Patent Kokai Publication No. JP2007-87467A

### SUMMARY

The entire disclosure of the above Patent Document is incorporated herein by reference thereto. The following analysis is given according to the views of the present invention.

Nowadays, in the fastest SpeedBin (DDR3-2133N) prescribed by JEDE (Joint Electron Device Engineering Council) that prescribes a synchronous DRAM standard, CL (CAS Latency) of 14 is supported. The CL tends to increase in order to meet the demand of higher speed. This increases required number of pointers. Therefore, the circuit size increases, if the circuit comprises latch circuits connected in series in order to perform shift operations. Thus, there is much to be desired in the art to provide a circuit with a reduced number of elements.

According to a first aspect of the present invention, there is provided a state detection circuit comprising: a first counter circuit that counts a series of first command signals indicative of start of an operation control;

a second counter circuit that counts a series of second command signals indicative of completion of the operation control;
a count coincidence detection circuit that detects coincidence between a count in the first counter circuit and a count in the second counter circuit; and
a state storing circuit that is set by the series of first command signals and reset when coincidence is detected by the count coincidence detection circuit; wherein
the first and second counter circuits each comprise a binary counter.

The present invention provides the following advantage, but not restricted thereto. According to the present invention, it is possible to provide a circuit with a reduced number of elements.

### BRIEF DESCRIPTION OF THE DRAWINGS

FIG. 1 is a block diagram illustrating a structure of a state detection circuit according to a first example.

FIG. 2 is a first timing chart for a state detection circuit according to a first example.

FIG. 3 is a circuit diagram of a counter circuit according to a first example.

FIG. 4 is a circuit diagram illustrating an example of a one-bit counter.

FIG. 5 is a circuit diagram illustrating an example of a count coincidence detection circuit.

FIG. 6 is a second timing chart for a state detection circuit according to a first example.

FIG. 7 is a circuit diagram illustrating a conventional data transfer completion detection circuit.

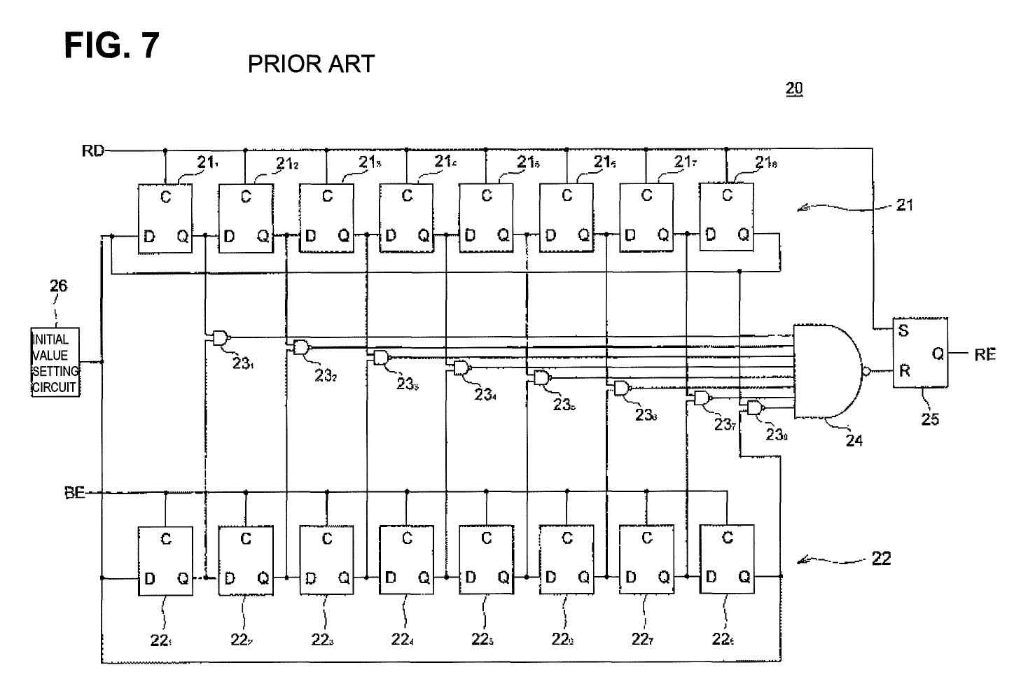

FIG. 8 is a block diagram illustrating a structure of a state detection circuit according to a second example.

### PREFERRED MODES

### Exemplary Embodiment

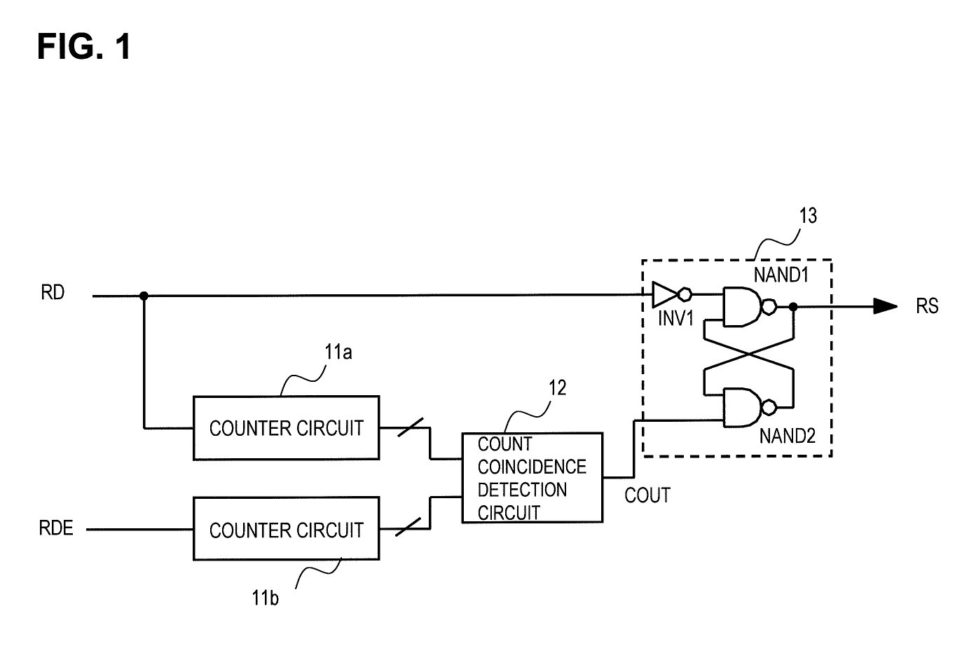

A state detection circuit according to an exemplary embodiment comprises: a first counter circuit (counter circuit 11a in FIG. 1) that counts a series of first command signals indicative of start of an operation control; a second counter circuit (counter circuit 11b in FIG. 1) that counts a series of second command signals indicative of completion of the operation control; a count coincidence detection circuit (count coincidence detection circuit 12 in FIG. 1) that detects coincidence between a count in the first counter circuit and a count in the second counter circuit; and a state storing circuit (RS flip flop circuit 13 in FIG. 1) that is set by the series of first command signals and reset when coincidence is detected by the count coincidence detection circuit. The first and second counter circuits each comprise a binary counter.

In the state detection circuit, the binary counter may comprise k flip flop circuits where k is the number of the series of first command signals to be counted and satisfies 2^{k-1}<n≦2^{k} and n, where n is an integer not less than two.

In the state detection circuit, the operation control may comprise a control of a read operation of a semiconductor memory device.

In the state detection circuit, the operation control may comprise a control of a write operation of a semiconductor memory device.

A semiconductor memory device may comprise the above state detection circuit.

A counter based not on a shift register but on a binary counter is employed in order to manage the number of commands in the above state detection circuit. A counter based on the shift register requires, for example, sixteen flip flop circuits in order to manage sixteen commands. On the other hand, a counter based on the binary counter of, e.g., four bits can count sixteen commands. A single bit of a binary counter can be constituted by a flip flop circuit and an additional circuitry. Therefore, the size of the circuit for controlling an operation of a semiconductor memory device is extremely reduced, when the number of pointers is increased,

In the following, examples are described with reference to the drawings.

### Example 1

FIG. 1 is a block diagram illustrating a structure of a state detection circuit according to a first example. The state detection circuit in FIG. 1 is applicable to a semiconductor memory devise, more specifically to an SDRAM. The state detection circuit comprises counter circuits 11a and 11b, a count coincidence detection circuit 12, and an RS flip flop circuit 13.

The counter circuit 11a is a counter for managing command reception and counts the number of level transition of a read command signal RD indicative of start of a read operation. The counter circuit 11b is a counter for managing command processing completion and counts the number of level transition of a read end command signal RDE indicative of completion of a read operation. The count coincidence detection circuit 12 receives a count in the counter circuit 11a and a count in the counter circuit 11b, determines whether or not these counts coincide, and, if these counts coincide, outputs a comparison result output signal COUT to the RS flip flop circuit 13.

The RS flip flop circuit 13 comprises an inverter circuit INV1, and two-input NAND circuits NAND1 and NAND2. The NAND circuit NAND1 receives from one of the input terminals a logically inverted signal of the read command signal RD through the inverter circuit INV1, receives from the other of the input terminals an output signal of the NAND circuit NAND2, and outputs a read state signal RS to the output terminal. The NAND circuit NAND2 receives a comparison result output signal COUT from one of the input terminals and receives an output signal of the NAND circuit NAND1 from the other of the input terminals. The RS flip flop circuit 13 configured in this way is set by the read command signal RD and reset by the comparison result output signal COUT, and outputs the read state signal RS.

Both counts in the counter circuits 11a and 11b are . . . 000 (binary value) just after they have been reset (not shown in the drawings). When the read command signal RD is inputted, the counter circuit 11a counts up to . . . 001 and the RS flip flop circuit 13 is set to activate the read state signal RS. When second and third read command signals RD are inputted, the counter circuit 11a counts up to . . . 010 and . . . 011.

After some cycles have elapsed and the process corresponding to the first read command signal RD has been completed, a read end command signal RDE is inputted and the counter circuit 11b counts up to . . . 001. When the processes corresponding to second and third read command signals have been completed, the counter circuit 11b counts up to . . . 010 and . . . 011. When input of a read command signal RD from outside ceases and the processes corresponding to entire read command signals have been completed, the counts in the counter circuits 11a and 11b become equal (have the same bit pattern). The count coincidence detection circuit 12 detects this state and generates a comparison result output signal COUT as a reset signal for the RS flip flop circuit 13. When processes corresponding to the entire read command signals have been completed and the count coincidence detection circuit 12 outputs a comparison result output signal COUT, the read state signal RS is set to an inactive state.

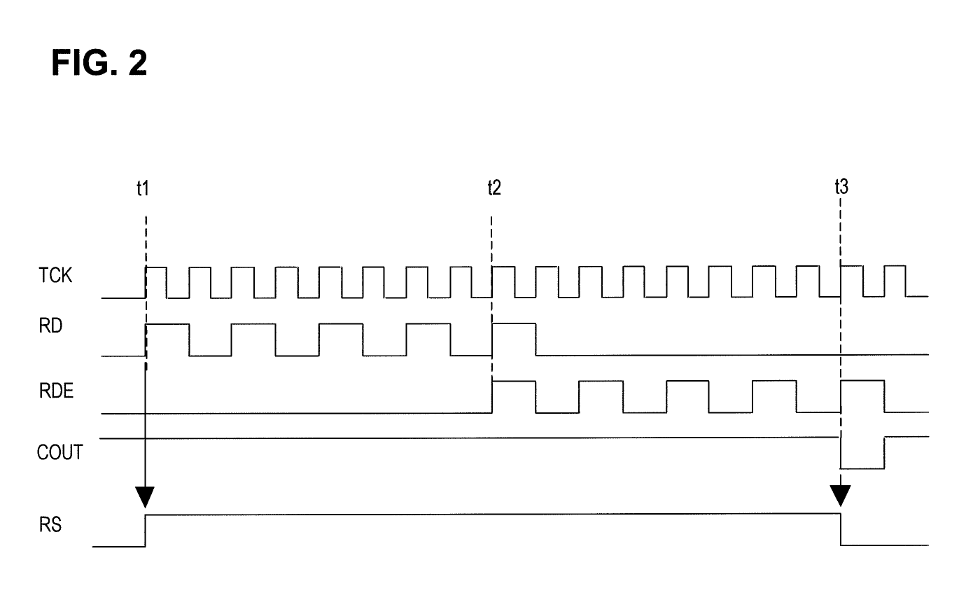

FIG. 2 is a first timing chart of a state detection circuit according to a first example. It is to be assumed that the read command signal RD and read end command signal RDE are inputted in synchronization with a system clock signal TCK. At a timing t1, the read command signal RD rises and the RS flip flop circuit 13 outputs a read state signal RS of H level. It is to be assumed that the read end command signal RDE rises at a timing t2 at which the read command signal RD makes a fifth transition to H level. At a timing t3, at which the read end command signal RDE makes a fifth transition to H level, the count coincidence detection circuit 12 detects coincidence between the count in the counter circuit 11a and the count in the counter circuit 11b and sets the comparison result output signal COUT to L level. Since the RS flip flop circuit 13 is reset due to coincidence between the number of transitions of the read command signal RD and the number of transitions of the read end command signal RDE, the RS flip flop circuit 13 outputs a read state signal RS of L level.

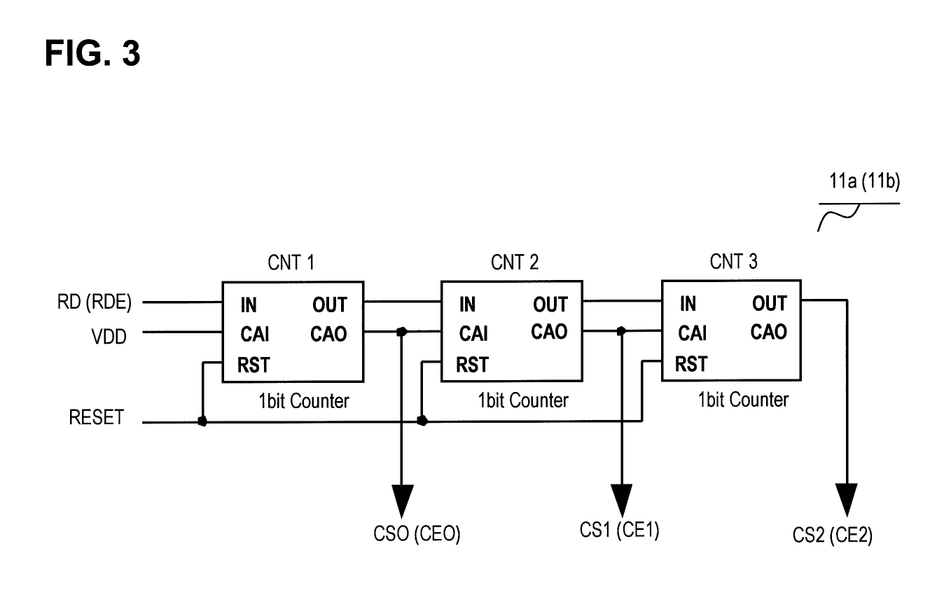

The detail of each unit composing the state detection circuit is described in the following. FIG. 3 is a circuit diagram illustrating counter circuits 11a and 11b. The counter circuits 11a and 11b have the same structure and comprise, for example, three one bit counters CNT1 to CNT3. The counter CNT1 receives a reset signal RESET from a reset terminal RST, receives a read command signal RD (and a read end command signal RDE) from an input terminal IN and receives a power voltage VDD from an input terminal CAI. An output terminal OUT of the counter CNT1 is connected to an input terminal IN of the counter CNT2. An output terminal CAO of the counter CNT1 is connected to an input terminal CAI of the counter CNT2 and outputs a count signal CS0 (CE0).

The counter CNT2 receives a reset signal RESET from a reset terminal RST. An input terminal IN of the counter CNT2 is connected to the output terminal OUT of the counter CNT1, an input terminal CAI of the counter CNT2 is connected to the output terminal CAO of the counter CNT1. An output terminal OUT of the counter CNT2 is connected to an input terminal IN of the counter CNT3. An output terminal CAO of the counter CNT2 is connected to an input terminal CAI of the counter CNT3 and outputs a count signal CS1 (CE1).

The counter CNT3 receives a reset signal RESET from a reset terminal RST. An input terminal IN of the counter CNT3 is connected to the output terminal OUT of the counter CNT2. An input terminal CAI of the counter CNT3 is connected to the output terminal CAO of the counter CNT2. The counter CNT3 outputs a count signal CS2 (CE2) from an output terminal OUT.

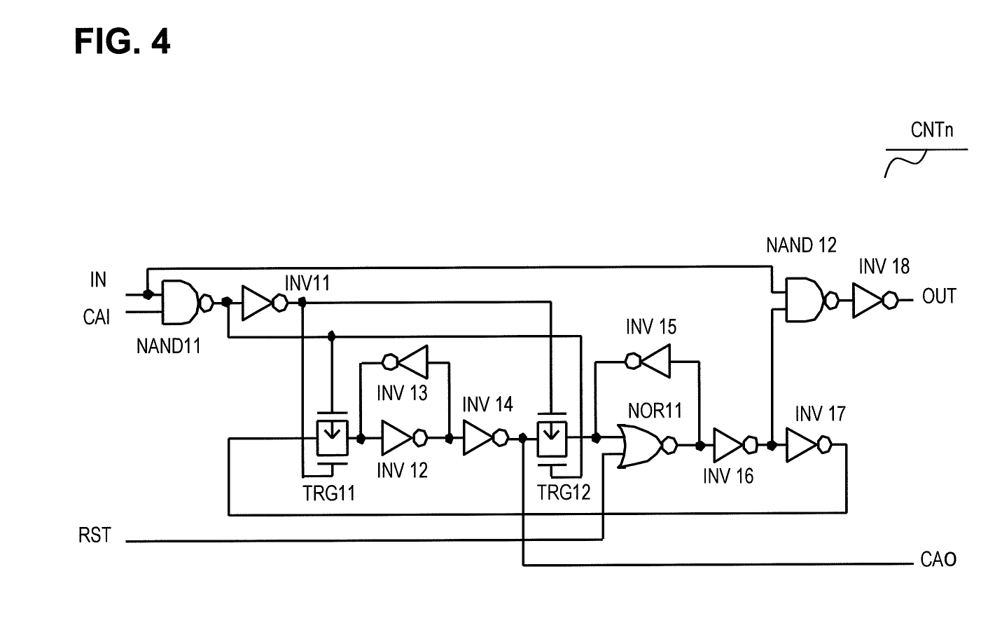

The detail of the counters CT1 to CT3 is described in the following. FIG. 4 is a circuit diagram illustrating an example of one bit counter CNTn (n=1 to 3). The counter CNTn comprises inverter circuits INV11 to INV18, NAND circuits NAND11 and NAND12, a NOR circuit NOR11, and transfer gate circuits TRG11 and TRG12.

The NAND circuit NAND11 performs a logical AND between inputs from input terminals IN and CAI followed by an inversion to perform an open/close control of the transfer gate TRG11. The inverter circuit INV11 performs logical inversion of the output signal from the NAND circuit NAND11 to perform an open/close control of the transfer gate TRG12 exclusively with respect to the transfer gate TRG11.

One terminal of the transfer gate circuit TRG11 is connected to an input terminal of the inverter circuit INV12 and an output terminal of the inverter INV13. The other terminal of the transfer gate circuit TRG11 is connected to an output terminal of the inverter circuit INV17. An input terminal of the inverter circuit INV14 is connected to an input terminal of the inverter circuit INV13 and an output terminal of the inverter circuit INV12. An output terminal of the inverter circuit INV14 is connected to one terminal of the transfer gate TRG12 and output terminal CAO.

The other terminal of the transfer gate circuit TRG12 is connected to one input terminal of the NOR circuit NOR11 and an output terminal of the inverter circuit INV15. The other input terminal of the NOR circuit NOR11 is connected to the reset terminal RST. An output terminal of the NOR circuit NOR11 is connected to an input terminal of then inverter circuit INV15 and an input terminal of the inverter circuit INV16.

One input terminal of the NAND circuit NAND12 is connected to the input terminal IN. The other input terminal of the NAND circuit NAND12 is connected to an output terminal of the inverter circuit INV16 and an input terminal of the inverter circuit INV17. An output terminal of the NAND circuit NAND12 is connected to the output terminal OUT through the inverter circuit INV18.

The counter CNTn configured as described above comprises a latch circuit including the inverter circuits INV12 and INV13 and a latch circuit including the inverter circuit INV15 and NOR circuit NOR11. The transfer gate circuits TRG11 and TRG12 perform open/close control of the connection between these two latch circuits, and the latch circuits function as a flip flop circuit that operates in response to the level transition of the signal inputted from the input terminal IN if the input terminal CAI is at H level. Therefore, the two latch circuits making up the counter CNTn function as a one bit counter that operates in response to the level transition of the signal inputted from the input terminal IN to H level.

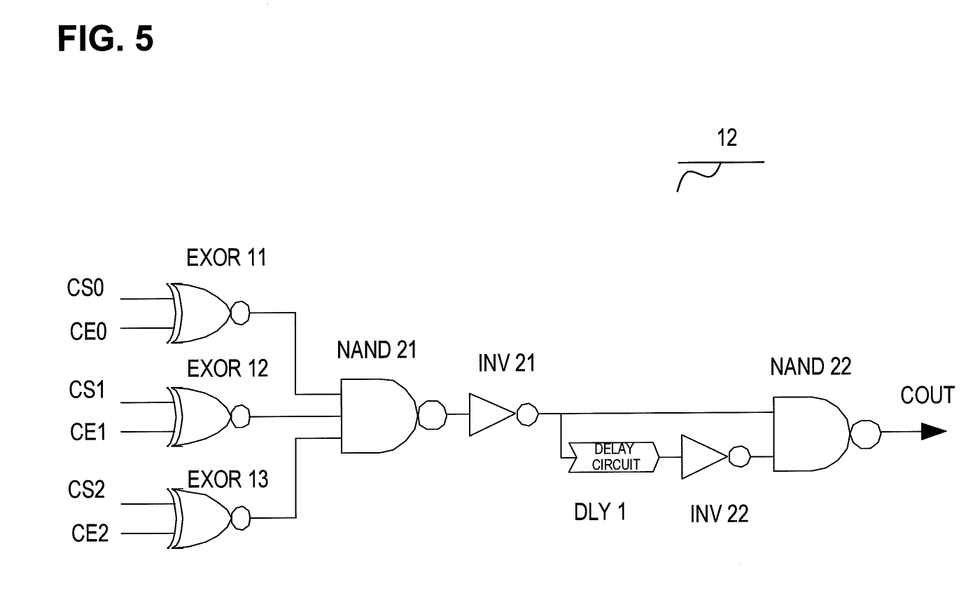

FIG. 5 is a circuit diagram illustrating an example of a count coincidence detection circuit 12. The count coincidence detection circuit 12 comprises inverted excusive OR circuits EXOR1n (n=1 to 3), NAND circuits NAND21 and NAND22, inverter circuits INV21 and INV22, and a delay circuit DLY1. The exclusive OR circuit EXOR1n performs an exclusive OR between count signals CSn-1 and CEn-1 and, outputs the logical inversion of the exclusive OR to an input terminal of the NAND circuit NAND21. The output signal of the NAND circuit NAND 21 is connected through the inverter circuit INV21 to one input terminal of the NAND circuit NAND22 and an input terminal of the delay circuit DLY1. The output signal of the delay circuit DLY1 is connected through the inverter circuit INV22 to the other input terminal of the NAND circuit NAND22. The NAND circuit NAND22 outputs a comparison result output signal COUT of L level during a delay time of the delay circuit DLY1 if the count signals CSn-1 and CEn-1 are coincident for n=1 to 3 as a whole.

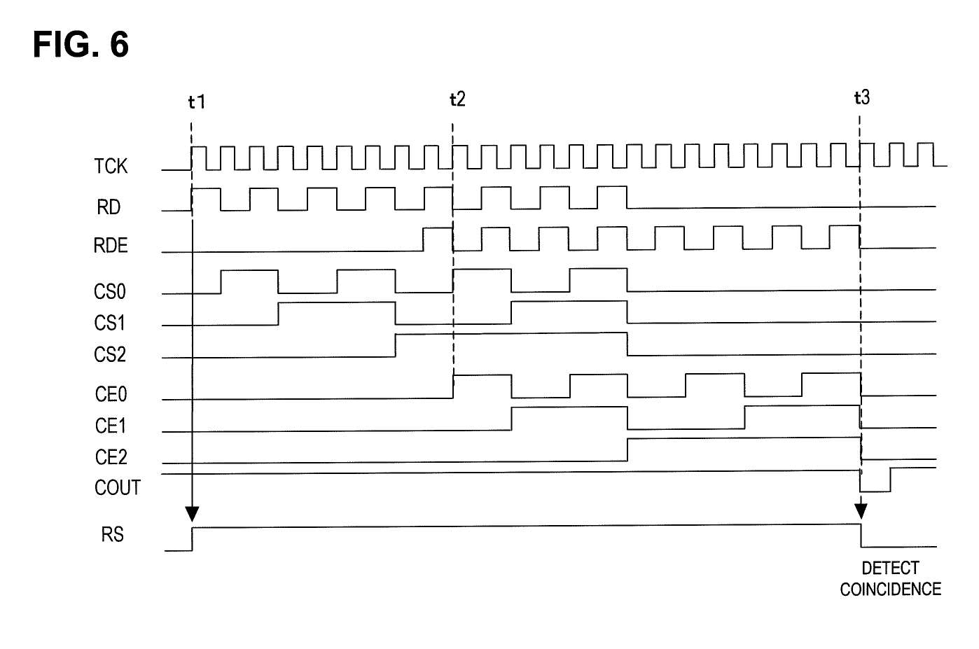

FIG. 6 is a second timing chart of the state detection circuit according to a first example. The basic content of the timing chart shown in FIG. 6 is the same as that of the first timing chart shown in FIG. 2. It is to be assumed that the read command signal RD and read end command signal RDE transition between H level and L level eight times, respectively.

The count signal CS0 makes a transition every time the read command signal RD makes a transition to L level. The count signal CS1 makes a transition every time the count signal CS0 makes a transition to L level. The count signal CS2 makes a transition every time the count signal CS1 makes a transition to L level.

In a similar manner, the count signal CE0 makes a transition every time the read end command signal RDE makes a transition to L level. The count signal CE1 makes a transition every time the count signal CE0 makes a transition to L level. The count signal CE2 makes a transition every time the count signal CS1 makes a transition to L level. At a timing t3, coincidence between the count signals CSn-1 and CEn-1 for n=1 to 3 is detected and the comparison result output signal COUT makes a transition to L level. Therefore, the read state signal RS, which has made a transition to H level at the timing t1, makes a transition to L level at the timing t3.

According to the state detection circuit as describe above, it is possible to construct a one bit counter circuit with the size of a flip flop circuit and an additional circuitry as shown in FIG. 4. Therefore, the number of circuit elements is extremely reduced as compared with the conventional state detection circuit realized using a shift register.

In the above, a state detection circuit related to a read operation is explained. However, the present invention is not limited to this case. The state detection circuit according to the present invention may receive, for example, a write command signal indicative of start of a write operation and a write end command signal indicative of completion of the write operation, instead of receiving the read command signal RD indicative of start of a read operation and the read end command signal RDE indicative of completion of the read operation. According to this state detection circuit, there is provided a circuit related to a write operation.

### Example 2

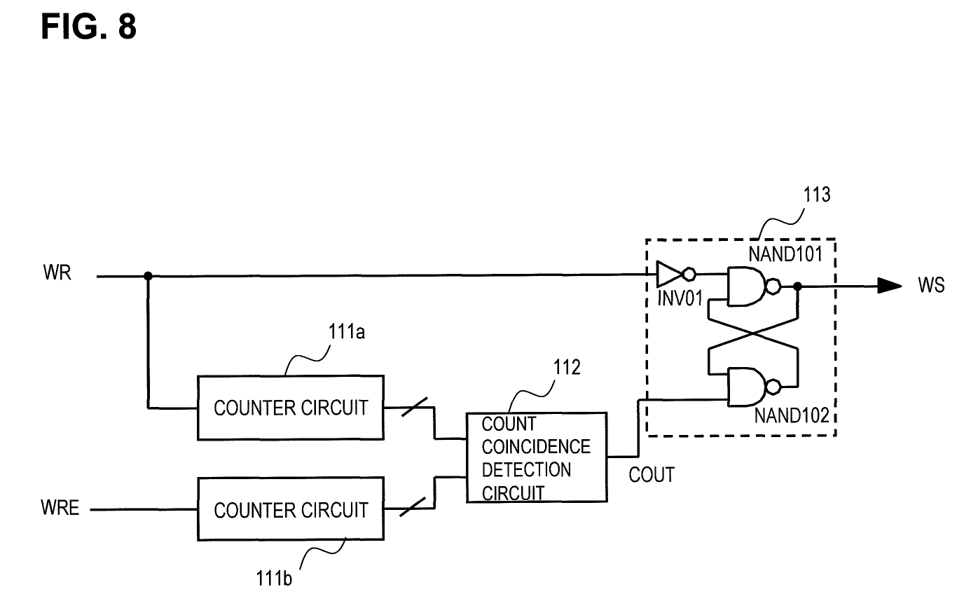

FIG. 8 is a block diagram illustrating a structure of a state detection circuit according to a second example. The state detection circuit in FIG. 8 is applicable to a semiconductor memory devise, more specifically to an SDRAM. The state detection circuit comprises counter circuits 111a and 111b, a count coincidence detection circuit 112, and an RS flip flop circuit 113.

The counter circuit 111a is a counter for managing command reception and counts the number of level transition of a write command signal WR indicative of start of a write operation. The counter circuit 111b is a counter for managing command processing completion and counts the number of level transition of a write end command signal WRE indicative of completion of a write operation. The count coincidence detection circuit 112 receives a count in the counter circuit 111a and a count in the counter circuit 111b, determines whether or not these counts coincide, and, if these counts coincide, outputs a comparison result output signal COUT to the RS flip flop circuit 113.

The RS flip flop circuit 113 comprises an inverter circuit INV101, and two-input NAND circuits NAND101 and NAND102. The NAND circuit NAND101 receives from one of the input terminals a logically inverted signal of the write command signal WR through the inverter circuit INV101, receives from the other of the input terminals an output signal of the NAND circuit NAND102, and outputs a write state signal WS to the output terminal. The NAND circuit NAND102 receives a comparison result output signal COUT from one of the input terminals and receives an output signal of the NAND circuit NAND101 from the other of the input terminals. The RS flip flop circuit 113 configured in this way is set by the write command signal WR and reset by the comparison result output signal COUT, and outputs the write state signal WS.

Both counts in the counter circuits 111a and 111b are . . . 000 (binary value) just after they have been reset (not shown in the drawings). When the write command signal WR is inputted, the counter circuit 111a counts up to . . . 001 and the RS flip flop circuit 113 is set to activate the write state signal WS. When second and third write command signals WR are inputted, the counter circuit 111a counts up to . . . 010 and . . . 011.

After some cycles have elapsed and the process corresponding to the first write command signal WR has been completed, a write end command signal WRE is inputted and the counter circuit 111b counts up to . . . 001. When the processes corresponding to second and third write command signals have been completed, the counter circuit 111b counts up to . . . 010 and . . . 011. When input of a write command signal WR from outside ceases and the processes corresponding to entire write command signals have been completed, the counts in the counter circuits 111a and 111b become equal (have the same bit pattern). The count coincidence detection circuit 112 detects this state and generates a comparison result output signal COUT as a reset signal for the RS flip flop circuit 113. When processes corresponding to the entire write command signals have been completed and the count coincidence detection circuit 112 outputs a comparison result output signal COUT, the write state signal WS is set to an inactive state.

The entire disclosures of above Patent Document are incorporated herein by reference thereto. In the framework of entire disclosure of the present invention (including the claims), and based on its basic technological idea, exemplary embodiments or examples of the present invention may be changed and/or adjusted. Also it should be noted that in the framework of the claims of the present invention, any combinations or selections of various elements disclosed herein are possible. That is, needless to say, it is understood by those skilled in the art that various changes or modifications can be made to the present invention based on the disclosure of the present invention including the claims and the technological idea of the present invention.

1. A state detection circuit comprising:
a first counter circuit that includes a plurality of unit frequency dividing circuits which are coupled between a first input node and a first output node in series, and that counts first command signals input to the first input node indicative of start of an operation control;
a second counter circuit that includes a plurality of unit frequency dividing circuits which are serially coupled between a second input node and second output node in series, and that counts second command signals input to the second input node indicative of completion of the operation control; and
a count coincidence detection circuit that couples to the first and second nodes, and that detects coincidence between a count in the first counter circuit and a count in the second counter circuit.

2. The state detection circuit according to claim 1, wherein each of the plurality of unit frequency dividing circuits comprises k flip flop circuits where k is the number of the series of first command signals to be counted and satisfies 2^{k-1}<n≦2^{k} and n, where n is an integer not less than two.

3. The state detection circuit according to claim 1, wherein the operation control comprises a control that is related to a read operation of a semiconductor memory device.

4. The state detection circuit according to claim 1, wherein the operation control comprises a control that is related to a write operation of a semiconductor memory device.

5. A semiconductor memory device including a state detection circuit, the state detection circuit comprising;
a first counter circuit that includes a plurality of unit frequency dividing circuits which are coupled between a first input node and a first output node in series, and that counts first command signals input to the first input node indicative of start of an operation control;
a second counter circuit that includes a plurality of unit frequency dividing circuits which are serially coupled between a second input node and second output node in series, and that counts second command signals input to the second input node indicative of completion of the operation control; and
a count coincidence detection circuit that couples to the first and second nodes, and that detects coincidence between a count in the first counter circuit and a count in the second counter circuit.

6-8. (canceled)

9. The state detection circuit according to claim 1, further comprising a state storing circuit that is set by the first command signals and reset when coincidence is detected by the count coincidence detection circuit.

10. The device according to claim 5, further comprising a state storing circuit that is set by the first command signals and reset when coincidence is detected by the count coincidence detection circuit.

11. The device according to claim 5, wherein each of the plurality of unit frequency dividing circuits comprises k flip flop circuits where k is the number of the series of first command signals to be counted and satisfies 2^{k-1}<n≦2^{k} and n, where n is an integer not less than two.

12. The device according to claim 5, wherein the operation control comprises a control that is related to a read operation of a semiconductor memory device.

13. The device according to claim 5, wherein the operation control comprises a control that is related to a write operation of a semiconductor memory device.
